(19) United States
(12) Patent Application Publication
(10) Pub. No.: US 2026/0331188 A1
(43) Pub. Date: Oct. 22, 2026

(54) FLOATING BODY EFFECT ACCUMULATION MITIGATION OPERATIONS IN A MEMORY SYSTEM

(71) Applicant: Micron Technology, Inc., Boise, ID (US)

(72) Inventors: Bryan David Kerstetter, Kuna, ID (US); Christopher John Kawamura, Boise, ID (US); Huan Chi Lung, Meridian, ID (US); Ben Wiggins, Boise, ID (US)

(21) Appl. No.: 19/635,292

(22) Filed: Mar. 31, 2026

Related U.S. Application Data
(60) Provisional application No. 63/792,803, filed on Apr. 22, 2025.

(51) Int. Cl. G11C 16/34; G11C 16/08; G11C 16/26

(52) U.S. Cl. CPC G11C 16/3418; G11C 16/08; G11C 16/26

(57) ABSTRACT

Methods, systems, and devices for floating body effect accumulation mitigation (FBEAM) operations in a memory system are described. A memory system may include a sense amplifier (SA) gap between subarrays of a memory array, where the SA gap comprises sense amplifiers for the subarrays. The memory system may include circuitry configured to determine whether to perform a refresh operation on the memory array or a FBEAM operation on the memory array based at least in part on a refresh command counter, wherein the FBEAM operation mitigates hole accumulation on access devices in the memory array. The memory system may also include a switching circuit coupled with the sense amplifiers of the SA gap and configured to supply the sense amplifiers with a voltage during the FBEAM operation. And the sense amplifiers of the SA gap may be configured to drive one or more digit lines to the voltage.

### CROSS REFERENCE

The present Application for Patent claims priority to U.S. Patent Application No. 63/792,803 by Kerstetter et al., entitled “FLOATING BODY EFFECT ACCUMULATION MITIGATION OPERATIONS IN A MEMORY SYSTEM,” filed Apr. 22, 2025, which is assigned to the assignee hereof, and which is expressly incorporated by reference in its entirety herein.

### TECHNICAL FIELD

The following relates to one or more systems for memory, including floating body effect accumulation mitigation (FBEAM) operations in a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports floating body effect accumulation mitigation (FBEAM) operations in a memory system in accordance with examples as disclosed herein.

FIG. 2 shows an example of a memory array that supports FBEAM operations in a memory system in accordance with examples as disclosed herein.

FIG. 3 shows an example of circuitry and an example of a timing diagram that supports FBEAM operations in a memory system in accordance with examples as disclosed herein.

FIG. 4 shows an example of a circuit that supports FBEAM operations in a memory system in accordance with examples as disclosed herein.

FIG. 5 shows an example of FBEAM trigger circuitry and address selection circuitry that support FBEAM operations in a memory system in accordance with examples as disclosed herein.

FIG. 6 shows an example of a circuit that supports FBEAM operations in a memory system in accordance with examples as disclosed herein.

FIG. 7 shows an example of FBEAM trigger circuitry and address selection circuitry that support FBEAM operations in a memory system in accordance with examples as disclosed herein.

FIG. 8 shows an example of a timing diagram that supports FBEAM operations in a memory system in accordance with examples as disclosed herein.

FIG. 9 shows an example of circuitry that supports FBEAM operations in a memory system in accordance with examples as disclosed herein.

FIG. 10 shows an example of a timing diagram that supports FBEAM operations in a memory system in accordance with examples as disclosed herein.

FIG. 11 shows a block diagram of a memory system that supports FBEAM operations in a memory system in accordance with examples as disclosed herein.

FIG. 12 shows a flowchart illustrating a method or methods that support FBEAM operations in a memory system in accordance with examples as disclosed herein.

### DETAILED DESCRIPTION

In some memory systems, the access devices (e.g., transistors) coupled with the memory cells of the memory system may have floating bodies (e.g., bodies between the drain and source terminals that are not coupled to ground). Such access devices may be susceptible to a floating body effect in which holes (e.g., positive charge) accumulate on the bodies of the access devices. As holes accumulate on the access devices, the threshold voltage of the access devices may decrease, which in turn may increase leakage of the memory cell and thus reduce the retention time of the memory cell. Reductions in retention time may increase the likelihood of data loss. So, hole accumulation on the access devices in a memory array may be associated with increased loss, among other disadvantages.

The techniques described herein enable a memory system to mitigate the floating body effect, which may improve retention and reliability of the memory system, among other advantages. Specifically, a memory system may perform a floating body effect accumulation mitigation (FBEAM) operation in which selected digit lines are coupled with a low voltage source (e.g., VSS, which may be 0 V or lower) so that the access devices enters a hole depletion state that reduces the holes on the body of the access device. The FBEAM operation may be triggered by a refresh command for a refresh operation and the memory system may perform the FBEAM operation instead of the refresh operation. For example, the memory system may perform the FBEAM operation every nth refresh command, an approach that may be referred to as “stealing” the refresh.

The memory system may include a memory array that is divided into sub-arrays that are separated by sense amplifier (SA) gaps which contain the sense amplifiers for the sub-arrays. In general, the sense amplifiers in an SA gap may be coupled with digit lines of the memory cells in two subarrays. During an FBEAM operation, the digit lines associated with the selected SA gap (e.g., the digit lines coupled with the sense amplifiers in the selected SA gap) may be coupled with the low voltage source via one or more switching circuits (e.g., one or more VBLP switches) for that SA gap. The SA gap for an FBEAM operation may be selected using a periodic technique or using a directed technique.

In a periodic FBEAM operation, the SA gap for the FBEAM operation may be selected based on an SA gap counter value, where different SA gap counter values are mapped to different SA gap addresses. A bank-specific SA gap decoder may resolve the SA gap counter value into an SA gap address and control the switching circuit(s) for that SA gap so the sense amplifiers in that SA gap (and thus the associated digit lines) are coupled with the low voltage source during the FBEAM operation.

In a directed FBEAM operation, the SA gap for the FBEAM operation may be selected from a bank-specific queue that holds the addresses of SA gaps in order of priority for FBEAM operations. The queue may be populated based on the values of SA gap-specific counters. For a given SA gap, the SA gap counter is incremented by an integer number every time interval that the SA gap is in the activate state associated with an activate command. A bank-specific SA gap decoder may use the SA gap address from the queue to control the switching circuit(s) for that SA gap so the sense amplifiers in that SA gap (and thus the associated digit lines) are coupled with the low voltage source during the FBEAM operation.

In addition to applicability in memory systems as described herein, techniques for retention aware refresh operations may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing data loss in memory cells and enabling use of weaker retention memory cells, which may support scaling for greater processing power.

In addition to applicability in memory systems as described herein, techniques for retention aware refresh operations may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing power draw of devices, as well as reducing material usage in manufacturing by reducing a die size in products. Further, the techniques described herein may enable use of a greater quantity of memory cells by allowing lower retention rates, which may increase manufacturing yield while reducing material waste caused by manufacturing redundant memory cells otherwise used to replace those with weaker retention characteristics.

Features of the disclosure are illustrated and described in the context of systems and architectures. Features of the disclosure are further illustrated and described in the context of retention distribution, retention distribution charts, flow diagrams, circuit diagrams, block diagrams, and flowcharts.

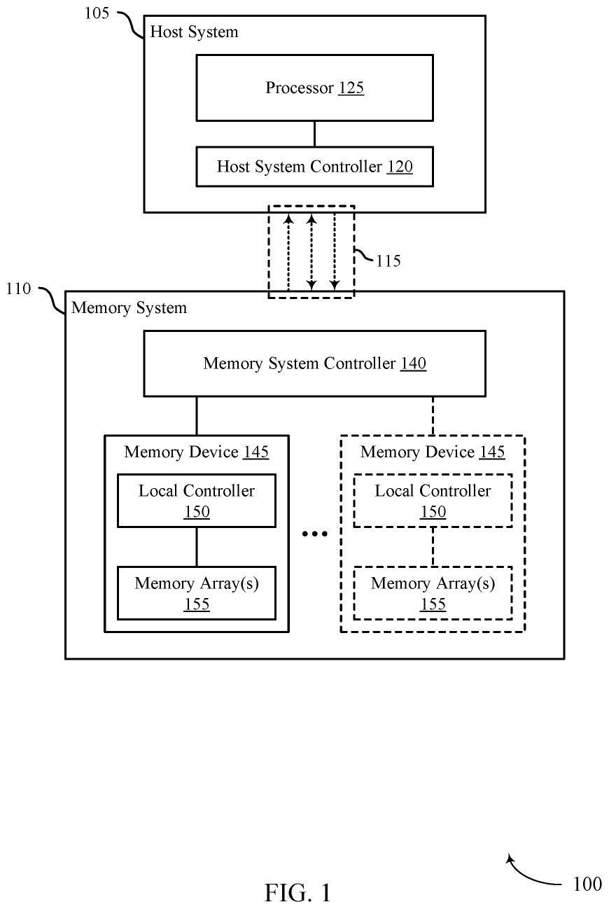

FIG. 1 shows an example of a system 100 that supports FBEAM operations in a memory system 110 in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

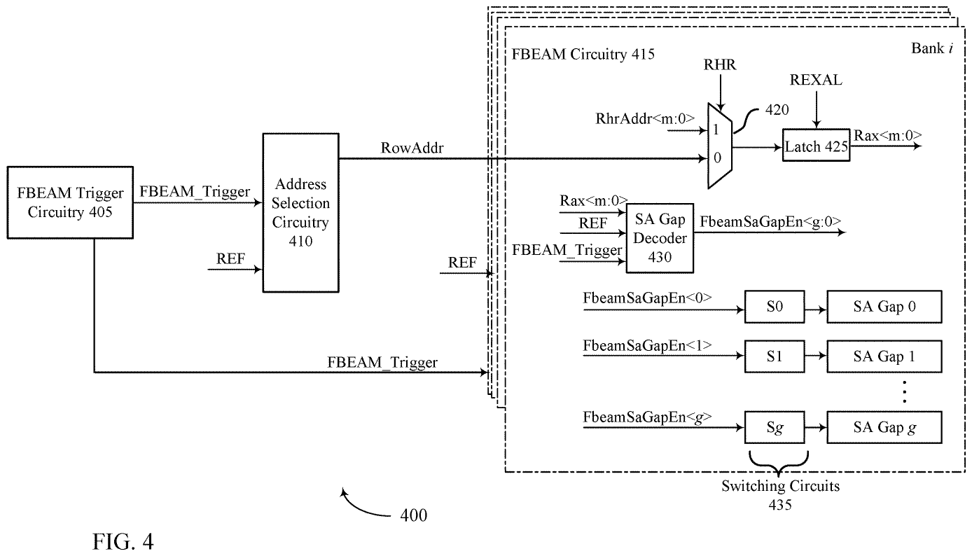

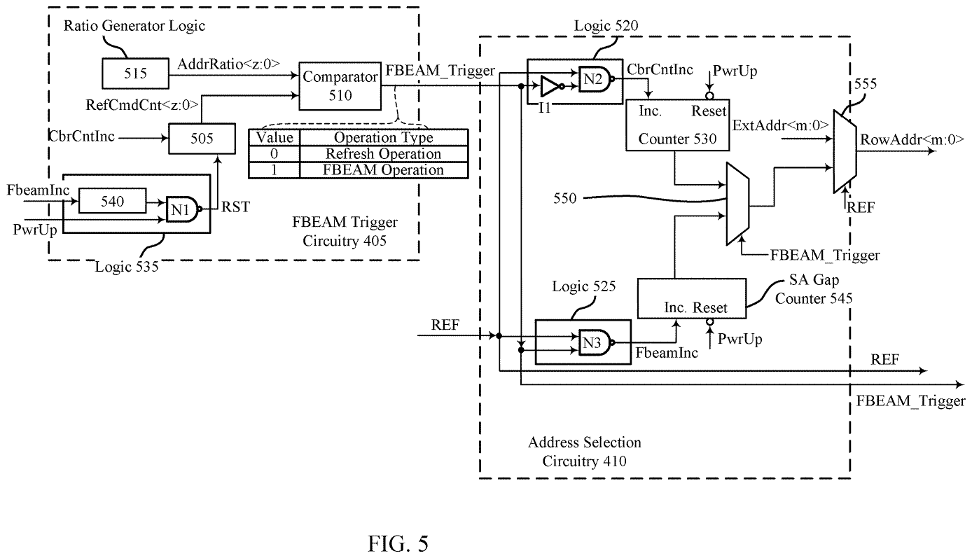

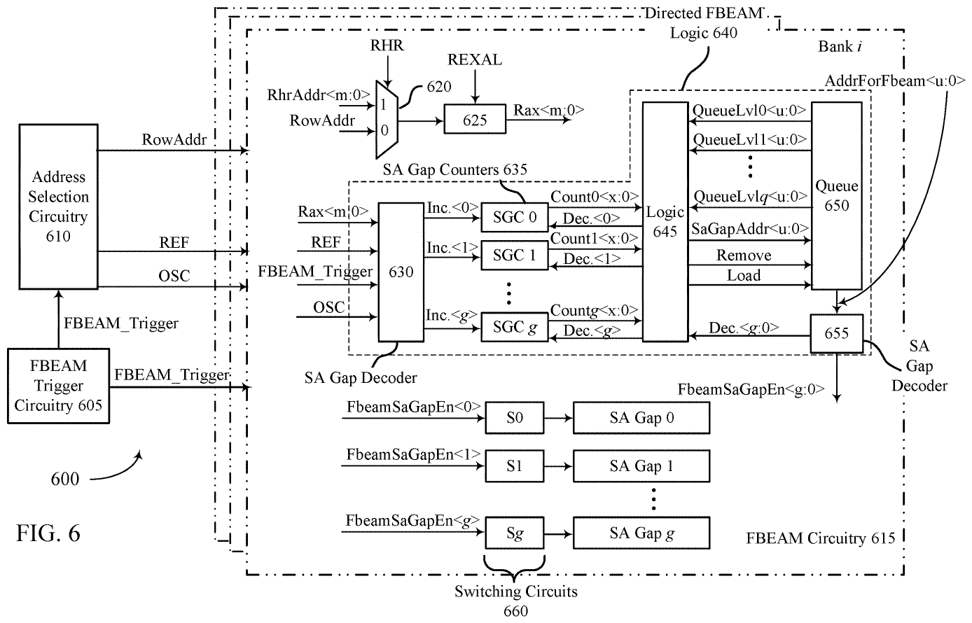

The memory cells in the memory arrays 155 may be coupled with access devices (e.g., transistors). If the access devices have floating bodies, holes may accumulate on the access devices when digit lines of the memory cells are in a certain state (e.g., applied with a high voltage). Such hole accumulation may negatively impact retention by increasing the threshold voltage of the access devices, because higher threshold voltages are associated with higher current leakage. To mitigate hole accumulation, the memory system 110 may perform FBEAM operations as described herein. During an FBEAM operation, the digit lines associated with an SA gap may be set to a hole depletion state (e.g., the digit lines may be driven to a low voltage) so that holes on the access device are decreased. The FBEAM operation may be triggered every nth refresh command and may performed for one or more SA gaps (or SA gap fractions) that are selected using the periodic technique (described with reference to FIGS. 4 and 5) or using the directed technique (described with reference to FIGS. 6-8). Although described separately, in some examples aspects of the periodic technique and the directed technique may be combined.

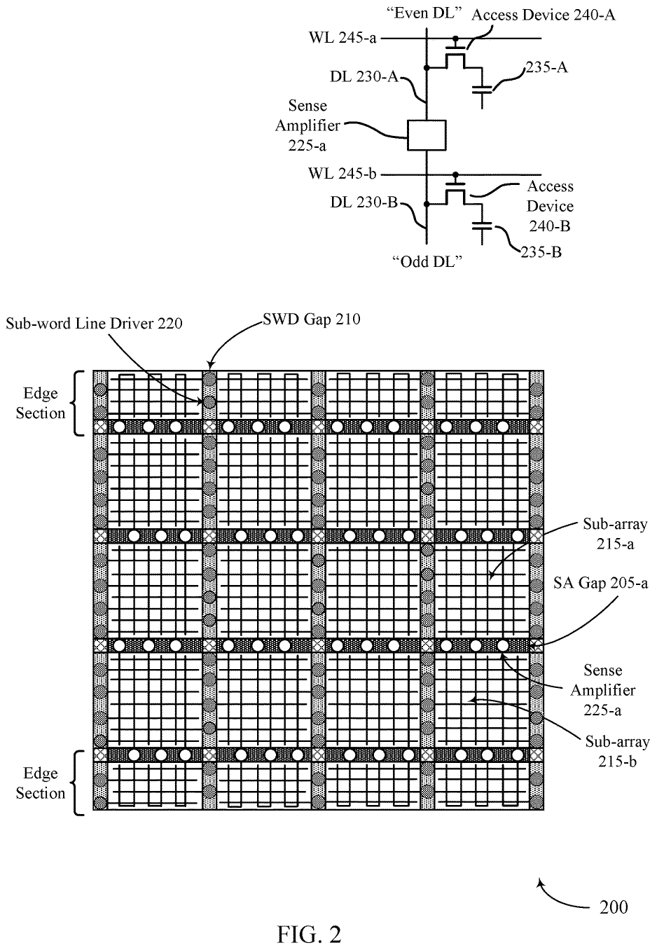

FIG. 2 illustrates an example of a memory array 200 that supports FBEAM operations in a memory system in accordance with examples as disclosed herein. The memory array 200 may be an example of a memory array 155 described with reference to FIG. 1. The memory array 200 may be divided (e.g., logically, physically) into sub-arrays 215 that are separated by SA gaps 205 and sub-word line driver gaps 210. The sub-arrays 215 may be grouped together into sections that include multiple sub-arrays 215. The sections may include edge sections (e.g., sections at the edge of the array 200 that are bordered by a single SA gap) and non-edge sections (e.g., sections that are bordered by two SA gaps). The SA gaps 205 may include sense amplifiers 225 for the sub-arrays 215, and the sub-word line driver gaps 210 may include sub-word line drivers 220 for the word lines. The sub-arrays 215 may include memory cells at the intersections of word lines (horizontal lines) and digit lines (vertical lines). Division of the memory array 200 into sub-arrays may reduce the lengths of the access lines associated with the sub-arrays, which may have various associated advantages.

The sense amplifiers 225 in an SA gap 205 may sense memory cells in the sub-array(s) 215 above SA gap 205 and the sub-array(s) 215 below the SA gap 205. For example, the sense amplifiers 225 in the SA gap 205-a may sense memory cells in the sub-array 215-a and memory cells in the sub-array 215-b. Accordingly, the sense amplifiers 225 in the SA gap 205-a may be coupled with digit lines of the memory cells in the sub-array 215-a and the sub-array 215-b. For example, as shown in the top figure, the sense amplifier 225-a may be coupled with the digit line 230-a, which may be coupled with the memory cell capacitor 235-a through the access device 240-a, and may be coupled with the digit line 230-b, which may be coupled with the memory cell capacitor 235-b through the access device 240-b. Thus, the sense amplifier 225-a may be coupled with at least one pair of memory cells. Alternating sections of the memory array 200 may be referred to as “even” sections and “odd” sections. Accordingly, the digit lines of the memory cells coupled with an SA gap 205 may be referred to as “even” digit lines or “odd” digit lines depending on the section in which they reside. Alternative terminology for differentiating sections and digit lines may be used, including referring to sections and digit lines as “upper” or “lower” depending on their positions relative to the reference SA gap 205.

The access devices 240 for the memory cells (e.g., access device 240-a, access device 240-b) may be coupled with respective word lines 245 (which may also be referred to as sub-word lines) that are driven by sub-word line drivers 220. A plurality (e.g., strip) of sub-word line drivers 220 may exist in a sub-word line driver gap 210. During an activate state, the sub-word line drivers 220 may drive the word lines to a high voltage (e.g., VCCP) to overcome the threshold voltage (Vt) drop across the access devices 240 to improve sensing performance. During a precharge state, the sub-word line drivers 220 may drive the word lines to a negative voltage (e.g., VNWL) so that leakage across the access devices 240 is reduced and retention is improved.

As the memory array 200 operates, the access devices 240 may enter hole accumulation states. For example, during an activate operation, one of the digit lines 230 may be driven high (e.g., into a hole accumulation state) and the other digit line 230 may be driven low. Over time, the hole accumulation on an access device 240 may alter the threshold voltage and reduce the retention time of the corresponding memory cell (e.g., due to increased current leakage).

Although the memory array 200 may support refresh operations to prevent memory cells from losing their programmed states, the refresh operations may not mitigate hole accumulation because in a refresh operation, one digit line is driven high (e.g., into a hole accumulation state) while the other digit line is driven low. So, the memory array 200 may use an FBEAM operation to mitigate hole accumulation.

To ensure that the FBEAM operation is triggered periodically, the memory array 200 may use refresh commands, of which there may be an overabundance, as the basis for triggering the FBEAM operation. For example, the FBEAM operation may be triggered every nth refresh command. During an FBEAM operation, digit lines coupled with the sense amplifiers in a selected SA gap 205 may be driven low (e.g., to a same voltage, such as VSS) so that the corresponding access devices are in a hole depletion state. So, unlike a refresh operation, which involves driving the word line high and driving the digit lines 230 to different voltages (one of which is associated with the hole accumulation state), the FBEAM operation involves maintaining the word line low and driving both digit lines 230 to the same low voltage level (which is associated with the hole depletion state).

During the FBEAM operation, the leakage of the access device 240 may be increased due to previous hole accumulation, due to a greater voltage difference across the access device 240 (e.g., because the digit line 230 is forced to VSS and the cell voltage may be at a high voltage), or both. To address this (e.g., to reduce increased leakage of the access devices 240 during the FBEAM operation), the voltage applied to the word lines 245 during the FBEAM operation may be reduced to a voltage level lower than the voltage VNWL (e.g., <VNWL) or to a voltage higher than VNWL (e.g., >VNWL).

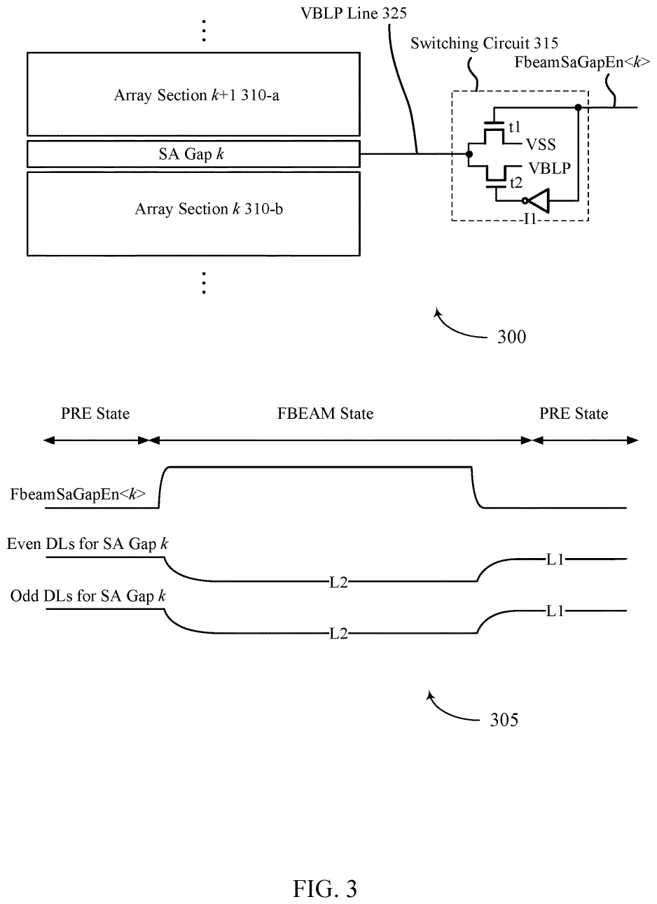

FIG. 3 shows an example of circuitry 300 and a timing diagram 305 that support FBEAM operations in a memory system in accordance with examples as disclosed herein. The circuitry 300 may be included in a memory device 145 and may include a memory array, such as the memory array 200, that has array section 310-a and array section 310-b. Each array section 310 may include one or more sub-arrays such as the sub-arrays 215 described with reference to FIG. 2. Accordingly, the array sections 310 may be coupled with, and separated by, an SA gap k. During an FBEAM operation for SA gap k, the sense amplifiers in SA gap k may be selectively coupled, via the switching circuit 315, with a low voltage source (e.g., VSS) so that digit lines coupled with the sense amplifiers in SA gap k can be driven low (e.g., into a hole depletion state). The switching circuit 315 may also be referred to as a VBLP switch or other suitable terminology.

The switching circuit 315 may selectively couple the sense amplifiers in the SA gap k with either a low voltage source (e.g., VSS) during an FBEAM operation or a high voltage source (e.g., VBLP) during normal operation. Specifically, the switching circuit 315 may couple the sense amplifiers in the SA gap k with the low voltage source during an FBEAM operation. The switching circuit 315 may include transistor t1, transistor t2, and inverter I1. When activated (e.g., when the control signal FbeamSaGapEn<k> goes high), transistor t2 may turn off and transistor t1 may turn on to couple the sense amplifiers in the SA gap k with the low voltage source via the VBLP line 325. Internally, each sense amplifier may be configured to couple digit lines associated with that sense amplifier with the VBLP line 325 so that the digit lines are driven low during the FBEAM operation. In some examples, the switching circuit 315 may couple the sense amplifiers in the SA gap k with a series of voltage sources so that the digit lines can be driven to a sequence of voltages.

Although illustrated and described with reference to the transistors t1 and t2 being NMOS transistors, the switching circuit 315 may be implemented using PMOS transistors for the transistors t1 and t2. In such cases, the control signal FbeamSaGapEn<k> may be brought low to activate transistor t1 and high to deactivate transistor t2. Further, with some additional changes, the transistors t1 and t2 may be implemented using a combination of NMOS and PMOS transistors (e.g., transistor t1 may be a PMOS transistor and transistor t2 may be an NMOS transistor, or vice versa). Alternatively, the transistors t1 and t2 may be implemented as other types of switching components.

Timing diagram 305 shows the control signal FbeamSaGapEn<k>, the voltage of the even digit lines for the SA gap k, and the voltage of the odd digit lines for the SA gap k. When the array sections 310 are in the precharge state, the control signal FbeamSaGapEn<k> may be low and the even digit lines and the odd digit lines may be at first level (e.g., L1). The even digit lines may refer to digit lines in the array section above the SA gap k (e.g., array section k+1), whereas the odd digit lines may refer to the digit lines in the array section below the SA gap k (e.g., array section k). When SA gap k is selected for an FBEAM operation (e.g., when the associated array sections 310 are in the FBEAM state), the control signal FbeamSaGapEn<k> may go high (e.g., activating transistor t1 and deactivating transistor t2) and the even digit lines and the odd digit lines may be reduced to a second level (e.g., L2) due to the coupling between the SA gap k and the low voltage source. The duration of the FBEAM state may be the duration of a refresh operation (e.g., tRFC). Alternatively, a different duration may be used for the FBEAM operation. In some cases, an example of the first level (e.g., L1) may be VBLP and an example of the second level (e.g., L2) may be VSS.

Although shown with one switching circuit 315 per SA gap, any quantity of switching circuits 315 may be used per SA gap. For example, if two switching circuits 315 are coupled with an SA gap, one switching circuit 315 may be coupled with half of the sense amplifiers in the SA gap whereas the other switching circuit 315 may be coupled with the other half of the sense amplifiers in the SA gap. Alternatively, one switching circuit 315 may be coupled with multiple SA gaps, or with a fraction of an SA gap. Thus, the switching circuit 315 to SA gap ratio may be 1:n or n:1. Accordingly, the number of sense amplifiers involved in an FBEAM operation may be associated with a fraction of an SA gap, an entire SA gap, or some number of SA gaps.

Thus, during an FBEAM operation, the switching circuit 315 may be used to drive digit lines associated with a selected SA gap to a voltage level associated with a hole depletion state.

In some examples, an FBEAM operation may be performed without the switching circuits 315. In a first example, the selected SA gap may be activated while a word line associated with the selected SA gap is activated. In a second example, the word line may not be activated and the method may step through columns instead of SA gaps. In a third example, the SA gaps may still be activated according to the periodic technique or directed technique described herein, and a word line associated with the SA gap (e.g., a word line in an even or odd section) may also be activated. In this example, digit lines associated with the SA gap may be pulled to either VARY or VSS. For example, half of the digit lines may be pulled to VSS (e.g., a hole depletion state) and the other half of the digit lines may be pulled to VARY (e.g., a hole accumulation state). Hole accumulation mitigation may be based on sensed data (e.g., a sense and flip procedure may be added). In some examples, a refresh command may be associated with refresh pumps, row hammer refresh pumps, and FBEAM pumps.

FIG. 4 shows an example of a circuit 400 that supports FBEAM operations in a memory system in accordance with examples as disclosed herein. The circuit 400 may include FBEAM trigger circuitry 405, address selection circuitry 410, and FBEAM circuitry 415. Details of the FBEAM trigger circuitry 405 and the address selection circuitry 410 are described with reference to FIG. 5. The circuit 400 may support periodic FBEAM operations that are applied to the SA gaps. Specifically, the circuit 400 enables selection of an SA gap for an FBEAM operation based on the value of an SA gap counter (e.g., the SA gap counter 545), where each value of the SA gap counter is mapped to a respective SA gap address. The FBEAM trigger circuitry 405 and the address selection circuitry 410 may be implemented as channel logic whereas the FBEAM circuitry 415 may be implemented as bank logic on a per-bank basis.

The FBEAM circuitry 415 may include switching circuits 435, which may be examples of the switching circuit 315 described with reference to FIG. 3. During an FBEAM operation, the switching circuits 435 may be used to couple a selected SA gap with a low voltage source so that digit lines associated with the selected SA gap can be driven to the low voltage. The FBEAM trigger circuitry 405, the address selection circuitry 410, and the rest of the FBEAM circuitry 415 may be supporting circuitry that determines when to perform an FBEAM procedure and that controls the switching circuits 435 to perform the FBEAM operation on one or more selected SA gaps.

The FBEAM trigger circuitry 405 may output the control signal FBEAM_Trigger which indicates, in response to a received refresh command, whether a refresh operation or an FBEAM operation is to be performed. The address selection circuitry 410 may select between values (e.g., an address for refresh and an SA gap counter value) and output the selected value as RowAddr over the row address bus. When an FBEAM operation is triggered, the selected value (e.g., RowAddr) may be the value of the SA gap counter (which has a corresponding SA gap address). After selecting between RowAddr and an address for Row Hammer Refresh (RHR)), the FBEAM circuitry 415 may decode the value of the SA gap counter to determine the corresponding SA gap address for the FBEAM operation, then control the switching circuits 435 so that the switching circuit(s) 435 associated with the SA gap address undergo(es) the FBEAM operation.

During an FBEAM operation, the FBEAM circuitry 415 may select between RowAddr, which may be the value of the SA gap counter, and RhrAdd<m:0>, which may be the address for a Row Hammer Refresh. For example, the selection component 420 may select RowAddr (instead of RhrAddr<m:0>) based on the value of the control signal RHR, which may indicate whether a Row Hammer Refresh operation is triggered. In some examples, the selection component 420 may be a multiplexer. In some examples, a refresh operation or a Row Hammer Refresh operation on one memory array may occur concurrent with an FBEAM operation on another memory array.

The latch 425 may latch the RowAddr value as Rax<m:0> based on the control signal REXAL. The latch 425 may be coupled with the SA Gap Decoder 430, which may receive Rax<m:0> from the latch 425 and decode Rax<m:0> by mapping the value of RowAdd (which is the value from the SA gap counter) to an SA gap address. The SA Gap Decoder 430 may decode Rax<m:0> based on the control signal REF, which may indicate a refresh command is to occur, and based on the control signal FBEAM_Trigger, which indicates the FBEAM operation is to occur.

The SA Gap Decoder 430 may output a control signal FbeamSaGapEn<g:0> that controls one or more switching circuits 435. For example, if the value of RowAdd is mapped to the address of SA gap 0, the SA Gap Decoder 430 may output control signal FbeamSaGapEn<0> to activate the S0 switching circuit coupled with SA gap 0. When activated, the S0 switching circuit may couple (e.g., via a VBLP line 325) SA gap 0 with a low voltage (e.g., VSS) that is associated with a hole depletion state for access devices (e.g., access devices 240) in the subarrays coupled with SA gap 0. The sense amplifiers in SA gap 0 may couple the VBLP line 235 with digit lines in the associated subarrays so that the digit lines are driven to the low voltage.

In some examples, the control signal FbeamSaGapEn<g:0> may also control additional switching circuits (e.g., switching circuits 920) so that one or more word lines associated with the subarrays is driven to a voltage lower than voltage VNWL (e.g., <VNWL) or a voltage higher than VNWL (e.g., >VNWL) during the FBEAM operation. Such a technique may reduce increased leakage of the implicated access devices during the FBEAM operation.

Thus, a periodic FBEAM operation may be implemented, which may mitigate the accumulation of holes on access devices in a memory array. In the circuit diagrams illustrated in the figures, if a signal outputted by a first component is inputted into a second component, it is understood that an output node of the first component is coupled with an input node of the second component, even if such a connection is not shown.

FIG. 5 shows an example of FBEAM trigger circuitry 405 and address selection circuitry 410 that support FBEAM operations in a memory system in accordance with examples as disclosed herein. As described with reference to FIG. 4, the FBEAM trigger circuitry 405 and the address selection circuitry 410 may be used, along with the FBEAM circuitry 415, to perform periodic FBEAM operations on a memory array. In response to an indication of a refresh command (REF) received by the address selection circuitry 410, the FBEAM trigger circuitry 405 may determine whether to perform an FBEAM operation or a refresh operation. If an FBEAM operation is triggered by the FBEAM trigger circuitry 405, the address selection circuitry 410 may select a value of the SA gap counter 545 (instead of the external address ExtAddr<m:0>) to output as RowAddr<m:0> over the row address bus. The value of the SA gap counter 545 may indicate the SA gap selected for the FBEAM operation so that FBEAM circuitry 415 can activate the switching circuit 435 for the selected SA gap.

The FBEAM trigger circuitry 405 may be configured to trigger FBEAM operations instead of executing refresh operations. The amount of FBEAM operations performed relative to refresh operations performed may be according to a ratio of refresh commands. For example, the FBEAM trigger circuitry 405 may be configured to trigger an FBEAM operation (instead of a refresh operation), every nth refresh command, where n is given by the AddrRatio<z:0>. The AddrRatio<z:0> may be generated by the ratio generator logic 515.

The FBEAM trigger circuitry 405 may include a refresh counter 505 that counts received refresh commands (e.g., based on performed refresh operations) and that outputs the quantity of refresh commands (RefCmdCnt<z:0>) to the comparator 510. The comparator 510 may compare the quantity of refresh commands to a threshold (AddrRatio<z:0>) and output the control signal FBEAM_Trigger based on the comparison. If the quantity of refresh commands is equal to the threshold, the FBEAM_Trigger may be a logic ‘1’ that indicates that an FBEAM operation is to be performed in response to the refresh command. If the quantity of refresh commands is not equal to the threshold, the FBEAM_Trigger may be a logic ‘0’ that indicates that refresh operation is to be performed in response to the refresh command.

The refresh counter 505 may count up to n before being reset, where n is equal to the AddrRatio. The value of the refresh counter 505 may be incremented after a normal refresh operation. In some examples, the value of the refresh counter 505 may be incremented based on the control signal CbrCntInc, which may be outputted by the logic 520 based on an indication of a refresh command indication (REF) and the control signal FBEAM_Trigger. For example, the refresh counter 505 may increment when the control CbrCntInc goes high, which may occur after refresh operation is triggered. The control signal CbrCntInc may also prompt the counter 530 to increment, where the value of the counter 530 indicates the quantity of refresh operations that have been performed since the memory array was powered up. The refresh counter 505 may be reset based on the control signal RST outputted by the logic 535, which may include a rising edge detector 540 and a NAND gate N1. The control signal RST may be based on the control signal PwrUp, which may indicate when the memory array is powered up (e.g., PwrUp may be low while the memory device is powering up), and based on the control signal FbeamInc, which may indicate when an FBEAM operation is triggered. Thus, the refresh counter 505 may be reset upon the powering up of the memory array or upon completion of an FBEAM operation.

The counter 530 may cycle every tREF (the time it takes for a normal refresh to occur for all cells of the die). The counter 530 may count through the array so that the entire array sees a refresh (e.g., every normal refresh command results a refresh operation to a different refresh address). The counter 530 may operate similar to the refresh counter 505, and thus in some examples one counter (e.g., a single counter) may be used to provide the functions associated with the counter 530 and the refresh counter 505.

The logic 520 may output the control signal CbrCntInc that prompts the counter 530 to increment after a refresh operation has completed. The control signal CbrCntInc may be based on the control signal FBEAM_Trigger and the control signal REF. The logic 520 may include an inverter I1 and a NAND gate N2. The NAND gate N2 may be functionally equivalent to an AND gate followed by an inverter.

The logic 525 may output the control signal FbeamInc that prompts the SA gap counter 545 to increment after an FBEAM operation has completed. The control signal FbeamInc may be based on the control signal FBEAM_Trigger and the control signal REF. The logic 525 may include a NAND gate N3. The NAND gate N3 may be functionally equivalent to an AND gate followed by an inverter

The counter 530 may count the quantity of refresh operations performed since powering up the memory array. The value of the counter 530 may be incremented based on the control signal CbrCntInc. For example, the value of the counter 530 may be incremented after a refresh operation is complete (e.g., at the rising edge of the control signal CbrCntInc). The counter 530 may be reset based on the control signal PwrUp. The counter 530 may output the current value of the counter 530 to the selection component 550, which may be a multiplexer.

The SA gap counter 545 may count the quantity of FBEAM operations performed since powering up the memory array. The value of the SA gap counter 545 may be incremented based on the control signal FbeamInc. For example, the value of the SA gap counter 545 may be incremented after an FBEAM operation has been completed (e.g., at the rising edge of the control signal FbeamInc). The SA gap counter 545 may be reset based on the control signal PwrUp. The SA gap counter 545 may output the current value of the SA gap counter 545 to the selection component 550.

The selection component 550 may select between a value from the SA gap counter 545 and a value from the counter 530. The selection component 550 may select between the values based on the control signal FBEAM_Trigger, which may indicate whether a refresh operation or an FBEAM operation is triggered. For example, the selection component 550 may select the value from the SA gap counter 545 if the control signal FBEAM_Trigger indicates that an FBEAM operation is triggered. Conversely, the selection component 550 may select the value from the counter 530 if the control signal FBEAM_Trigger indicates that a refresh operation is triggered. The value selected by the selection component 550 may be provided to the selection component 555.

The selection component 555 may select (e.g., for transmission over a row address bus) between a value from the selection component 550 and an external address ExtAddr<m:0> (e.g., for an activate command). The selection component 555 may select between the values based on the control signal REF. The value selected by the selection component 555 may be transmitted as RowAddr<m:0> over the row address bus coupled with the bank(s) of the memory device.

Thus, the FBEAM trigger circuitry 405 may determine when to perform an FBEAM operation and the address selection circuitry 410 may indicate the SA gap selected for the FBEAM operation (e.g., by selecting the value of the SA gap counter 545 for transmission to the FBEAM circuitry 415).

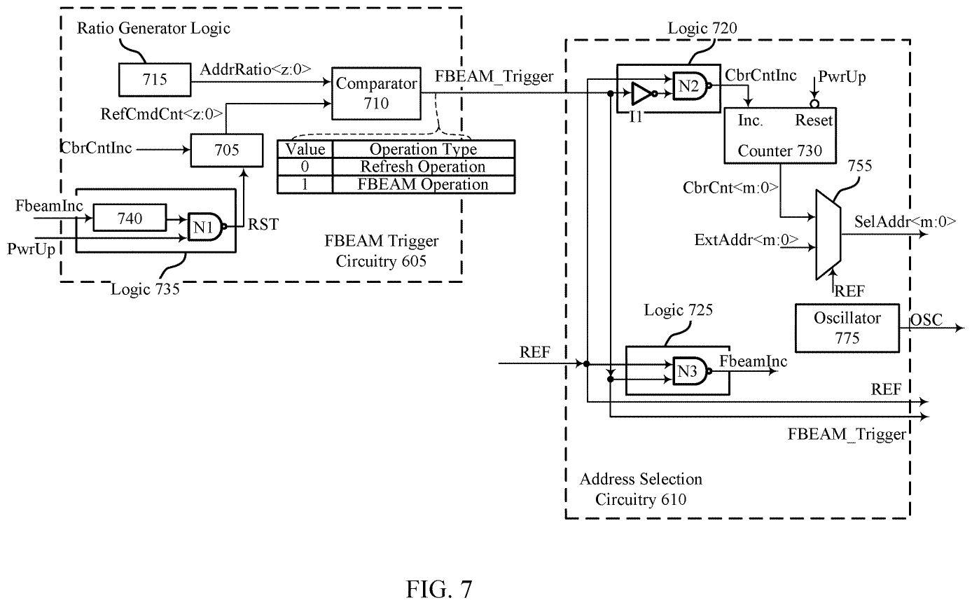

FIG. 6 shows an example of a circuit 600 that supports FBEAM operations in a memory system in accordance with examples as disclosed herein. The circuit 600 may include FBEAM trigger circuitry 605, address selection circuitry 610, and FBEAM circuitry 615. Details of the FBEAM trigger circuitry 605 and the address selection circuitry 610 are described with reference to FIG. 7. The circuit 600 may support directed FBEAM operations that are applied to the SA gaps on a priority-basis. Specifically, the circuit 600 enables selection of an SA gap for an FBEAM operation based on the address of the SA gap being included in the queue 650. The FBEAM trigger circuitry 605 and the address selection circuitry 610 may be implemented as channel logic whereas the FBEAM circuitry 615 may be implemented as bank logic on a per-bank basis.

The FBEAM circuitry 615 may include switching circuits 660, which may be examples of the switching circuit 315 described with reference to FIG. 3. During an FBEAM operation, the switching circuits 660 may be used to couple a selected SA gap with a low voltages so that digit lines associated with the selected SA gap can be driven to the low voltage. The FBEAM trigger circuitry 605, the address selection circuitry 610, and the rest of the FBEAM circuitry 615 may be supporting circuitry that determines when to perform an FBEAM procedure and that controls the switching circuits 660 to perform the FBEAM operation on one or more SA gaps selected for the FBEAM operation.

The SA gaps for an FBEAM operation may be selected from the queue 650 based on the priorities of the SA gap addresses in the queue 650 (e.g., the SA gap associated with the highest priority SA gap address may be selected). The queue 650 may be populated with SA gap addresses based on the values of the SA gap counters 635. For example, an SA gap address may be added to the queue 650 (e.g., by the logic 645) if the value of the SA gap counter 635 associated with that SA gap satisfies (e.g., is greater than) a threshold. The value of an SA gap counter 635 may represent an amount of time the sense amplifiers in that SA gap have spent in an activate state, which may be a potential hole accumulation state for the associated access devices. Thus, the value of an SA gap counter 635 may represent a worse-case amount of time an access device has spent in the accumulation state.

The FBEAM trigger circuitry 605 may provide the control signal FBEAM_Trigger to the FBEAM circuitry 615. The FBEAM_Trigger may indicate, in response to a received refresh command, whether a refresh operation or an FBEAM operation is to be performed.

The address selection circuitry 610 may provide RowAddr and the control signal REF to the FBEAM circuitry 615. When a refresh operation is triggered, RowAddr may be an address for a refresh operation; otherwise, RowAddr may be an address for a received activate command. The address selection circuitry 610 may also provide a clock signal OSC that is used by the FBEAM circuitry 615 to increment the SA gap counters 635, which are used as a basis to populate the queue 650.

When an FBEAM operation is triggered, the FBEAM circuitry 615 may select between RowAddr and RhrAdd<m:0>, which may be the address for a Row Hammer Refresh. For example, the selection component 620 may select RowAddr (instead of RhrAddr<m:0>) based on the value of the control signal RHR, which may indicate whether a Row Hammer Refresh operation is triggered. In some examples, the selection component 620 may be a multiplexer. In some examples, a refresh operation or a Row Hammer Refresh operation on one memory array may occur concurrent with an FBEAM operation on another memory array.

The latch 625 may latch the RowAddr value as Rax<m:0> based on the control signal REXAL. The latch 625 may be coupled with the directed FBEAM logic 640 and may provide the address Rax<m:0> to the directed FBEAM logic 640 (e.g., to the SA gap decoder 630). The directed FBEAM logic 640 may be added per bank, per fraction of a bank, or per a multiplicity of banks.

The SA gap decoder 630 may decode the address Rax<m:0> to determine the associated SA gap and control the SA gap counters 635 (e.g., using control signals Inc. <0> through Inc. <g>) based on the clock signal OSC. For example, if the SA gap decoder 630 determines that the address Rax<m:0> is the address for SA gap 0, the SA gap decoder 630 may increment the corresponding SA gap counter 635 (e.g., the SA gap counter SGC 0) every time interval (e.g., every h μs) that the SA gap 0 is in an activate state (e.g., due to an activate operation, which may be triggered by an activate command, a refresh command, or some other command). The SA gap decoder 630 may additionally or alternatively increment the SA gap counter 635 corresponding to an SA gap based on receipt of the activate command for the SA gap. If incrementation of the SA gap decoders 630 is exclusively conditioned on receipt of an activate command, the address selection circuitry 610 may omit the oscillator 775.

The SA gap counters 635 may provide (e.g., as Count0<x:0> through Countg<x:0>) the values of the SA gap counters 635 to the logic 645. As noted, the value of an SA gap counter 635 may represent an amount of time that the corresponding SA gap has spent in an activate state. The SA gap counters 635 may be controlled by the SA gap decoder 630 and by the logic 645. For example, an SA gap counter 635 may increment its value based on a control signal from the SA gap decoder 630, and may decrement its value based on a control signal from the logic 645.

The logic 645 may determine SA gap addresses to add to (and remove from) the queue 650 based on the values of the SA gap counters 635. For example, the logic 645 may compare the value of an SA gap counter 635 with a threshold and prompt (e.g., using the control signal Load) the queue 650 to add the corresponding SA gap address (e.g., as address SaGapAddr<u:0>) to the queue 650 if the value satisfies (e.g., exceeds) the threshold (e.g., an FBEAM threshold). If the value of an SA gap counter 635 is less than the threshold, the logic 645 may prompt (e.g., using control signal Remove) the queue 650 to remove the corresponding SA gap address from the queue 650. From the queue 650, the logic 645 may receive signaling (e.g., control signals QueueLvl0<u:0> through QueueLvlq<u:0>, where the queue depth is q+1) that indicates the contents of the queue 650. As noted, the queue depth (e.g., how many SA gap addresses (or levels) can fit in the queue 650) may be represented by q+1. Therefore, QueueLvl0<u:0> may be the SA Gap Address associated with the zeroth level (lvl) of the queue 650. Furthermore, QueueLvlq<u:0> may be the SA Gap Address associated with the q'th level of the queue 650. And so on and so forth for the other levels of the queue 650.

The logic 645 may also control the SA gap counters 635. For example, the logic 645 may prompt the SA gap counter 635 to decrement their values (e.g., by a fixed amount) by providing the control signals Dec.<0> through Dec.<g>. The logic 645 may prompt an SA gap counter 635 to decrement its value based on performing an FBEAM operation on the SA gap associated with that SA gap counter 635. Alternatively, the logic 645 may prompt an SA gap counter 635 to reset its value based on performing an FBEAM operation on the SA gap associated with that SA gap counter 635. The logic 645 may decrement (or reset) the SA gap counter 635 indicated by the control signal Dec.<g:0>, which may be outputted by the SA gap decoder 655 when an FBEAM operation is performed on the SA gap associated with the SA gap counter 635.

The queue 650 may store SA gap addresses for FBEAM operations as well as the priorities of the SA gap addresses. The queue 650 may add an SA gap address (e.g., SaGapAddr<u:0>) provided by the logic 645 based on the control signal Load. If the SA gap address indicated by the logic 645 is already in the queue 650, the queue 650 may increase the priority assigned to that SA gap address. The queue 650 may remove an SA gap address from the queue 650 as prompted (e.g., using the control signal Remove) by the logic 645. When an FBEAM operation is triggered, the queue 650 may provide the highest priority SA gap address (e.g., as AddrForFbeam<u:0>) to the SA gap decoder 655.

The SA gap decoder 655 may decode SA gap addresses received from the queue 650 and output a control signal FbeamSaGapEn<g:0> to control the switching circuits 660. For example, for an FBEAM operation, the SA gap decoder 655 may determine the SA gap and switching circuit 660 that correspond to an SA gap address and prompt the corresponding switching circuit 660 to activate. Accordingly, the corresponding SA gap, and digit lines coupled with the sense amplifiers in the SA gap, may be driven to a low voltage (e.g., VSS) associated with a hole depletion state.

Although shown with one SA gap counter 635 per SA gap, any quantity of SA gap counters 635 may be used per SA gap. For example, multiple SA gap counters 635 may be associated with an SA gap, in which case each SA gap counter 635 for the SA gap may be associated with a respective portion of the SA gap. Alternatively, one SA gap counter 635 may be associated with multiple SA gaps. Thus, the SA gap counter 635 to SA gap ratio may be 1:n or n:1. The SA gap counter 635 to SA gap ratio may be based on the ratio of switching circuits 315 to SA gaps. Further, the quantity of SA gap counters 635 may determine the size of the SA gap decoder 630, the logic 645, the queue 650, and the SA gap decoder 655. That is, the sizes of these components may be based on the quantity of SA gap counters 635. Additionally, the quantity of the SA gap counters 635 may be related to the quantity of switching circuits 660 and SA gaps.

Thus, a directed FBEAM operation may be implemented, which may mitigate the accumulation of holes on access devices in a memory array.

FIG. 7 shows an example of FBEAM trigger circuitry 605 and address selection circuitry 610 that support FBEAM operations in a memory system in accordance with examples as disclosed herein. As described with reference to FIG. 6, the FBEAM trigger circuitry 605 and the address selection circuitry 610 may be used, along with the FBEAM circuitry 615, to perform directed FBEAM operations on a memory array. In response to an indication of a refresh command (REF) received by the address selection circuitry 610, the FBEAM trigger circuitry 605 may determine whether to perform an FBEAM operation or a refresh operation. If an FBEAM operation is triggered by the FBEAM trigger circuitry 605, the address selection circuitry 610 may select the CbrCntInc<m:0> (instead of the ExtAddr<m:0> address for a refresh operation) to output as SelAddr<m:0> over the row address bus, where SelAddr<m:0> represents the selected address (e.g., either ExtAddr<m:0> or CbrCnt<m:0>). The address selection circuitry 610 may also output a clock signal OSC (generated by the oscillator 775) that is used by the FBEAM circuitry 615 to increment the SA gap counters 635.

Although the address selection circuitry 610 is configured so that CbrCnt<m:0> is selected during a Directed FBEAM operation (e.g., because REF is high), to save power, the selection component 755 may be alternatively configured so that the select input could be forced low (e.g., so that the ExtAddr is selected during a directed FBEAM cycle) as it would be during normal (e.g., non-FBEAM and non-refresh) operation. Unlike a periodic FBEAM operation, a directed FBEAM operation may not make use of the global Row Address Bus (e.g., RowAddr<m:0>). Therefore the selection component 755 during a directed FBEAM operation may select either CbrCnt<m:0> or ExtAddr<m:0>. That is, the value of the Row Address Bus (e.g., RowAddr<m:0>) may be inconsequential during a directed FBEAM operation.

Similar to the FBEAM trigger circuitry 405, the FBEAM trigger circuitry 605 may be configured to trigger FBEAM operations at a ratio of refresh commands. For example, the FBEAM trigger circuitry 605 may be configured to trigger an FBEAM operation (instead of a refresh operation), every nth refresh command, where n is given by the AddrRatio<z:0>. The AddrRatio<z:0> may be generated by the ratio generator logic 715.

The FBEAM trigger circuitry 605 may include a refresh counter 705 that counts received refresh commands and that outputs the quantity of refresh commands (RefCmdCnt<z:0>) to the comparator 710. The comparator 710 may compare the quantity of refresh commands to a threshold (AddrRatio<z:0>) and output the control signal FBEAM_Trigger based on the comparison. If the quantity of refresh commands is equal to the threshold, the FBEAM_Trigger may be a logic ‘1’ that indicates that an FBEAM operation is to be performed in response to the refresh command. If the quantity of refresh commands is not equal to the threshold, the FBEAM_Trigger may be a logic ‘0’ that indicates that refresh operation is to be performed in response to the refresh command.

The refresh counter 705 may count up to n before being reset, where n is equal to the AddrRatio. The value of the refresh counter 705 may be incremented based on the control signal CbrCntInc, which may be outputted by the logic 720 based on an indication of a refresh command indication (REF) and the control signal FBEAM_Trigger. The control signal CbrCnt may also prompt the counter 730 to increment, where the value of the counter 730 indicates the quantity of refresh operations that have been performed since the memory array was powered up.

The refresh counter 705 may be reset based on the control signal RST outputted by the logic 735, which may include a rising edge detector 740 and a NAND gate N1. The control signal RST may be based on the control signal PwrUp, which may indicate when the memory array is powered up (e.g., PwrUp may be low while the memory device is powering up), and based on the control signal FbeamInc, which may indicate when an FBEAM operation is triggered. Thus, the refresh counter 705 may be reset upon the powering up of the memory array or after a FBEAM operation completes. Similar to the counter 530, the counter 730 may cycle every tREF (the time it takes for a normal refresh to occur for all cells of the die). The counter 730 may count through the array so that the entire array sees a refresh (e.g., every normal refresh command results a refresh operation to a different refresh address).

The logic 720 may output the control signal CbrCntInc that prompts the counter 730 to increment after a refresh operation has completed. For example, the value of the counter 730 may be incremented after a refresh operation is complete (e.g., at the rising edge of the control signal CbrCntInc). The control signal CbrCntInc may be based on the control signal FBEAM_Trigger and the control signal REF. The logic 720 may include an inverter I1 and a NAND gate N2. The NAND gate N2 may be functionally equivalent to an AND gate followed by an inverter.

The logic 725 may output the control signal FbeamInc that serves as a basis for resetting the refresh counter 705. The control signal FbeamInc may be based on the control signal FBEAM_Trigger and the control signal REF. The logic 725 may include a NAND gate N3. The NAND gate N3 may be functionally equivalent to an AND gate followed by an inverter.

The selection component 755 may select (e.g., for transmission over a row address bus) between a value from the counter 730 and an external address ExtAddr<m:0> (e.g., for an activate command). The selection component 755 may select between the values based on the control signal REF. The value selected by the selection component 755 may be transmitted as SelAddr<m:0> over the row address bus coupled with the bank(s) of the memory device, where SelAddr<m:0> represents the selected address (e.g., either ExtAddr<m:0> or CbrCnt<m:0>).

The oscillator 775 may generate a clock signal OSC and output the clock signal OSC to the FBEAM circuitry 615. The clock signal OSC may be used as a basis for incrementing the SA gap counters 635. In some examples, the oscillator 775 may be enabled during an ACT procedure. In some examples, each bank may have its own oscillator (as opposed to the banks sharing the oscillator 775).

Thus, the FBEAM trigger circuitry 605 and the address selection circuitry 610 may support the performance of directed FBEAM operations by the FBEAM circuitry 615.

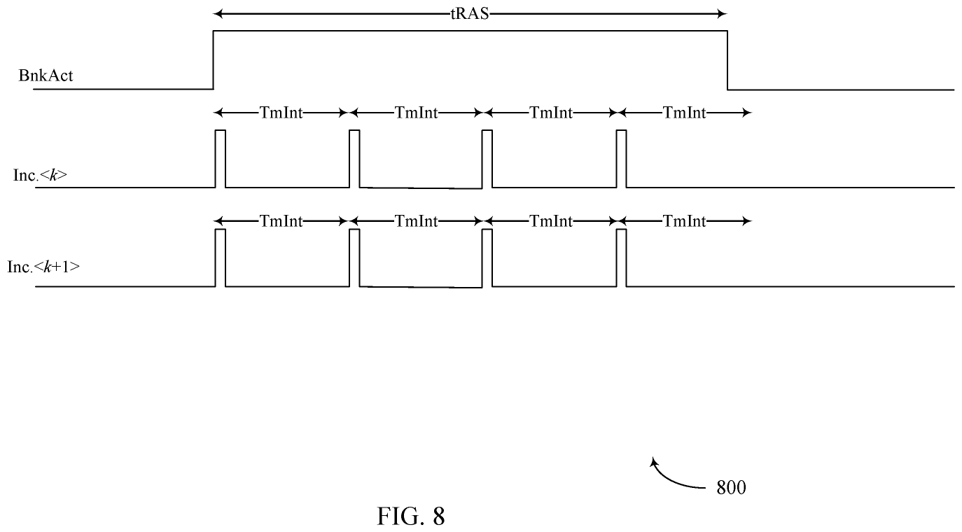

FIG. 8 shows an example of a timing diagram 800 that supports FBEAM operations in a memory system in accordance with examples as disclosed herein. The timing diagram 800 may support incrementation of SA gap counters 635 as described with reference to FIG. 6. Specifically, the timing diagram 800 may enable the memory system to increment the SA gap counters 635 for the even SA gap and the odd SA gap coupled with a section of a memory array that has received an activation command. The timing diagram 800 may illustrate a control signal BnkAct for activating a bank of the memory array, a control signal Inc. <k> to increment the SA gap counter 635 for SA gap k, and a control signal Inc. <k+1> to increment the SA gap counter 635 for SA gap k+1. The control signals Inc. <k> and Inc. <k+1> may be outputted by the SA gap decoder 630.

The control signal BnkAct may be high for a time period (e.g., tRAS). During this time period, the SA gaps associated with the control signal BnkAct may be in an activated state. The SA gap decoder 630 may pulse the control signal Inc. <k> and the control signal Inc. <k+1> based on the SA gaps entering the activated state, and again every time interval TmInt that the SA gaps are in the activated state. The time interval TmInt may be determined based on the clock signal (OSC).

Thus, the SA gap counters 635 may be incremented to support the directed FBEAM operation.

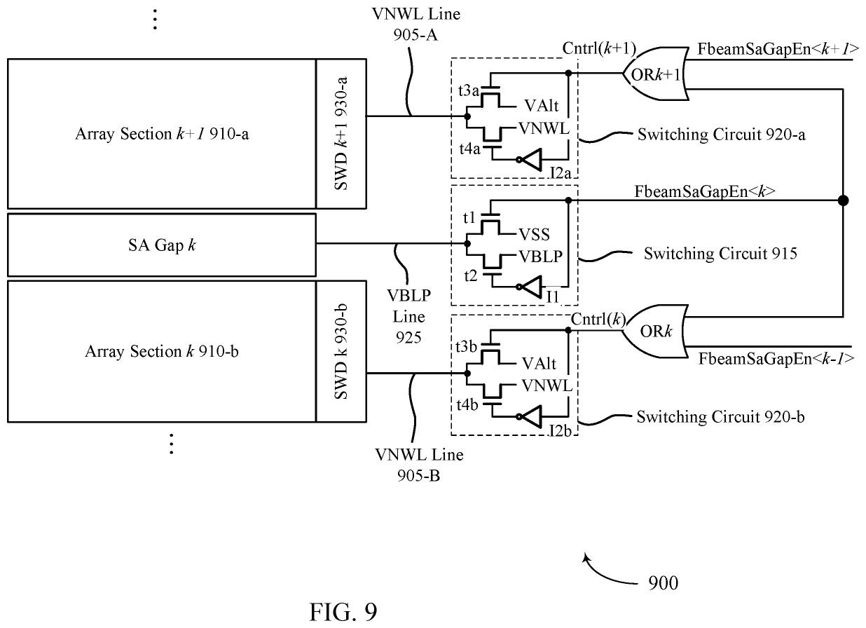

FIG. 9 shows an example of circuitry 900 that supports FBEAM operations in a memory system in accordance with examples as disclosed herein. The circuitry 900 may be included in a memory device 145 and may include a memory array, such as the memory array 200, that has array section 910-a (e.g., array section k+1) and array section 910-b (e.g., array section k). Each array section 910 may include one or more sub-arrays such as the sub-arrays 215 described with reference to FIG. 2. Accordingly, the array sections 910 may be coupled with, and separated by, an SA gap k. Each array section 910 may be coupled with a respective sub-word line driver 930 that is configured to drive the word lines of that array section 910 to various voltages. For example, array section 910-a may be coupled with sub-word line driver 930-a, and array section 910-b may be coupled with sub-word line driver 930-b.

As described with reference to FIG. 3, during an FBEAM operation for SA gap k, the sense amplifiers in SA gap k may be coupled, via the switching circuit 915, with a low voltage source (e.g., VSS) so that digit lines coupled with the sense amplifiers can be driven low (e.g., into a hole depletion state). Additionally, the sub-word line drivers 930 may be coupled, via the switching circuits 920, with a voltage source different than voltage VNWL (denoted VAlt) so that leakage across the access devices (e.g., access devices 240) in the array sections 910 is reduced and retention is improved. For example, the sub-word line drivers 930 may be coupled with a voltage source lower than voltage VNWL (e.g., <VNWL). Alternatively, the sub-word line drivers 930 may be coupled with a voltage source higher than voltage VNWL (e.g., >VNWL), which may allow the word lines associated with the sub-word line driver gap to be driven to any reasonable voltage without having to deal with a threshold voltage drop.

Although illustrated as an NMOS transistor, the transistors in FIG. 9 may be implemented as PMOS transistors or other switching components. Further, with some additional changes, the transistors in FIG. 9 may be implemented using a combination of NMOS and PMOS transistors (e.g., some transistors may be NMOS transistors and other transistors may be PMOS transistors).

The switching circuit 915 may operate similar to the switching circuit 315 described with reference to FIG. 3. For example, the switching circuit 915 may selectively couple the sense amplifiers in the SA gap k with either a low voltage source (e.g., VSS) during an FBEAM operation or a high voltage source (e.g., VBLP) during normal operation. Specifically, the switching circuit 915 may couple the sense amplifiers in the SA gap k with the low voltage source during an FBEAM operation. The switching circuit 915 may include transistor t1, transistor t2, and inverter I1. When activated (e.g., when the control signal FbeamSaGapEn<k> goes high), transistor t2 may turn off and transistor t1 may turn on to couple the sense amplifiers in the SA gap k with the low voltage source via the VBLP line 925. Internally, each sense amplifier may be configured to couple digit lines associated with that sense amplifier with the VBLP line 925 so that the digit lines are driven low during the FBEAM operation.

The switching circuits 920 may selectively couple the sub-word line drivers 930 with either the voltage source VNWL during normal operation or with a different voltage source VAlt during an FBEAM operation. The voltage source VAlt may be a lower voltage source (e.g., <VNWL) or a higher voltage source (e.g., >VNWL) relative to the voltage source VNWL. The switching circuits 920 may include transistors t3, transistors t4, and inverters I2. When activated (e.g., when the control signals Cntrl(k) and Cntrl(k+1) go high), transistors t4 may turn off and transistors t3 may turn on to couple the sub-word line drivers 930 with the voltage source VAlt via the VNWL line 905. Internally, the sub-word line drivers 930 may be configured to couple the word lines in the associated array section 910 with the VNWL line 905 so that the word lines are driven to the voltage VAlt (e.g., <VNWL or >VNWL) during the FBEAM operation. Although described as being driven to the voltage VAlt, the word lines may be driven to a voltage slightly lower than the voltage VAlt (e.g., due to a voltage drop that is dependent on the configuration of the switching circuits 920).

The control signals that control the switching circuits 920 may be outputted by the OR gates ORk and ORk+1. For example, the control signal Cntrl(k+1) that controls the switching circuit 920-a may be outputted by the OR gate ORk+1, and the control signal Cntrl(k) that controls the switching circuit 920-b may be outputted by the OR gate ORk.

Because the array section 910-a (e.g., array section k+1) is coupled with SA gap k and another SA gap (e.g., SA gap k+1) (not shown), the voltage of the sub-word line driver 930-a may be altered when an FBEAM operation is performed for either SA gap. Accordingly, the OR gate ORk+1 may receive the control signal FbeamSaGapEn<k> and the control signal FbeamSaGapEn<k+1>. Thus, the OR gate ORk+1 may control the switching circuit 920-a to couple the sub-word line driver 930-a with the voltage source VAlt when an FBEAM operation is performed for either SA gap k or SA gap k+1.

Similarly, because the array section 910-b (e.g., array section k) is coupled with SA gap k and another SA gap (e.g., SA gap k−1) (not shown), the voltage of the sub-word line driver 930-b may be altered when an FBEAM operation is performed for either SA gap. Accordingly, the OR gate ORk may receive the control signal FbeamSaGapEn<k> and the control signal FbeamSaGapEn<k−1>. Thus, the OR gate ORk may control the switching circuit 920-b to couple the sub-word line driver 930-b with the voltage source VAlt when an FBEAM operation is performed for either SA gap k or SA gap k−1.

Thus, during an FBEAM operation for SA gap k, the switching circuits 920 may be used to drive the word lines in array section k and array section k+1 to the voltage source VAlt (e.g., <VNWL, >VNWL).

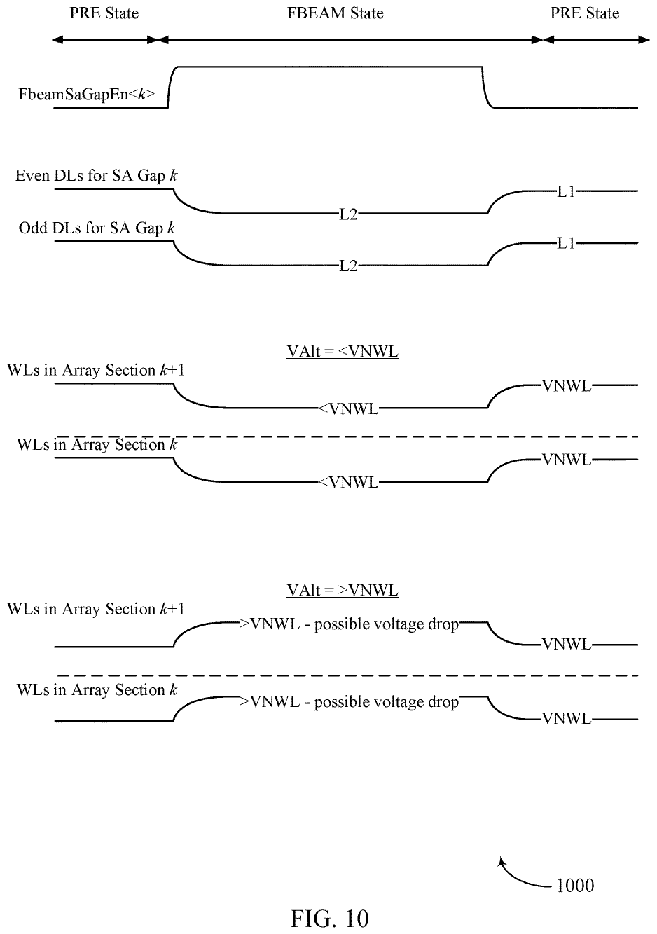

FIG. 10 shows an example of a timing diagram 1000 that supports FBEAM operations in a memory system in accordance with examples as disclosed herein. Timing diagram 1000 shows the control signal FbeamSaGapEn<k>, the voltage of the even digit lines for the SA gap k, and the voltage of the odd digit lines for the SA gap k. Timing diagram 1000 also shows the voltage of the word lines in array section k (e.g., array section 910-b) and the voltage of the word lines in array section k+1 (e.g., array section 910-a). As seen in the timing diagram 1000, when an FBEAM operation is performed on SA gap k, digit lines coupled with SA gap k may be driven to a low voltage level (e.g., level L2) and the word lines coupled with the array sections k and k+1 may be driven to the voltage VAlt (e.g., <VNWL or >VNWL).

For example, when the array sections 910 are in the precharge state, the control signal FbeamSaGapEn<k> may be low and the even digit lines and the odd digit lines may be at first level (e.g., L1). When SA gap k is selected for an FBEAM operation, the control signal FbeamSaGapEn<k> may go high and the even digit lines and the odd digit lines may be reduced to a second level (e.g., L2) due to the coupling between the SA gap k and the low voltage source.

Similarly, when the array sections 910 are in the precharge state, the control signal FbeamSaGapEn<k> may be low and the word lines in the array sections 910 may be at voltage VNWL. When SA gap k is selected for an FBEAM operation, the control signal FbeamSaGapEn<k> may go high and the word lines in the array sections 910 may be driven to voltage VAlt (when VAlt is reduced to a voltage <VNWL) or Valt minus a possible voltage drop (when Valt is increased to a voltage >VNWL) due to the coupling between the sub-word line drivers 930 and the voltage source VAlt.

Thus, during an FBEAM operation on SA gap k, digit lines coupled with SA gap k may be driven to a low voltage level (e.g., level L2) and the word lines coupled with the array sections k and k+1 may be driven to the voltage VAlt (or VAlt minus a possible voltage drop in the case that VAlt is >VNWL).

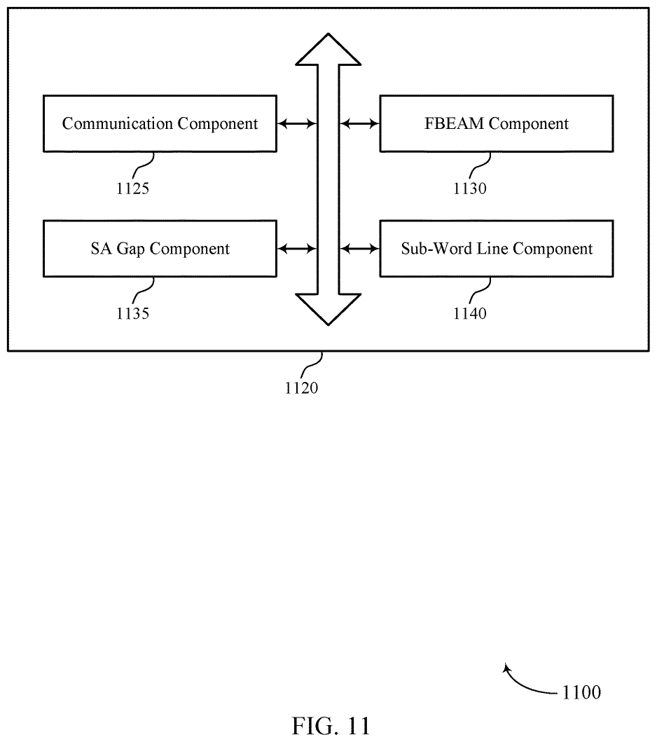

FIG. 11 shows a block diagram 1100 of a memory system 1120 that supports FBEAM operations in a memory system in accordance with examples as disclosed herein. The memory system 1120 may be an example of aspects of a memory system as described with reference to FIGS. 1 through 10. The memory system 1120, or various components thereof, may be an example of means for performing various aspects of FBEAM operations in a memory system as described herein. For example, the memory system 1120 may include a communication component 1125, an FBEAM component 1130, an SA gap component 1135, a sub-word line component 1140, or any combination thereof. Each of these components, or components of subcomponents thereof (e.g., one or more processors, one or more memories), may communicate, directly or indirectly, with one another (e.g., via one or more buses).

The communication component 1125 may be configured as or otherwise support a means for receiving a refresh command for a memory array including a plurality of sub-arrays separated by sense amplifier (SA) gaps, each SA gap including a respective plurality of sense amplifiers. The FBEAM component 1130 may be configured as or otherwise support a means for determining, in response to the refresh command, whether to perform a refresh operation on the memory array or a FBEAM operation on the memory array based at least in part on a refresh command counter, where the FBEAM operation mitigates hole accumulation on access devices in the memory array. In some examples, the FBEAM component 1130 may be configured as or otherwise support a means for selecting an SA gap for the FBEAM operation based at least in part on determining to perform the FBEAM operation. The SA gap component 1135 may be configured as or otherwise support a means for activating one or more switching circuits coupled with the selected SA gap to drive the respective plurality of sense amplifiers within the selected SA gap to a voltage during the FBEAM operation.

In some examples, each sense amplifier in the respective plurality of sense amplifiers within the selected SA gap is coupled with a respective pair of digit lines, and the SA gap component 1135 may be configured as or otherwise support a means for activating the respective plurality of sense amplifiers within the selected SA gap based at least in part on activating the one or more switching circuits, where the respective pair of digit lines coupled with each sense amplifier in the respective plurality of sense amplifiers is driven to the voltage based at least in part on activating the respective plurality of sense amplifiers.

In some examples, the FBEAM component 1130 may be configured as or otherwise support a means for comparing a value of a refresh counter to an address ratio value, where the value of the refresh counter represents a quantity of refresh operations that have been performed on the memory array, and where the FBEAM operation is determined to be performed based at least in part on the value of the refresh counter being equal to the address ratio value.

In some examples, the FBEAM component 1130 may be configured as or otherwise support a means for resetting the value of the refresh counter based at least in part on performing the FBEAM operation.

In some examples, the FBEAM component 1130 may be configured as or otherwise support a means for transmitting, over a row address bus, an indication of value of a counter to a bank including the memory array, where the value of the counter represents a quantity of FBEAM operations that have been performed on the memory array, and where the SA gap is selected for the FBEAM operation based at least in part on the value being associated with an address of the SA gap.

In some examples, the FBEAM component 1130 may be configured as or otherwise support a means for incrementing the value of the counter based at least in part on performing the FBEAM operation.

In some examples, the SA gap is selected for the FBEAM operation based at least in part on an address associated with the SA gap being included in a list of addresses stored by a queue. In some examples, the list of addresses includes addresses associated with SA gaps for FBEAM operations.

In some examples, the FBEAM component 1130 may be configured as or otherwise support a means for incrementing, based at least in part on an activate command for the SA gap, a value of a counter associated with the SA gap. In some examples, the FBEAM component 1130 may be configured as or otherwise support a means for determining that the value of the counter satisfies a threshold. In some examples, the FBEAM component 1130 may be configured as or otherwise support a means for adding the address associated with the SA gap to the queue based at least in part on the value of the counter satisfying the threshold, where selecting the SA gap is based at least in part on adding the address to the queue.

In some examples, the FBEAM component 1130 may be configured as or otherwise support a means for determining that the address associated with the SA gap is already in the queue. In some examples, the FBEAM component 1130 may be configured as or otherwise support a means for increasing a priority of the address based at least in part on the address already being in the queue, where selecting the SA gap is based at least in part on the priority of the address in the queue.

In some examples, the FBEAM component 1130 may be configured as or otherwise support a means for activating the respective plurality of sense amplifiers in the SA gap based at least in part on the activate command, where the value of the counter associated with the SA gap is incremented based at least in part on activating the respective plurality of sense amplifiers.

In some examples, the FBEAM component 1130 may be configured as or otherwise support a means for determining that the respective plurality of sense amplifiers have been activated for a threshold duration, where the value of the counter is incremented based at least in part on the respective plurality of sense amplifiers having been activated for the threshold duration.

In some examples, the SA gap is selected for the FBEAM operation based at least in part on a priority of the address, and the FBEAM component 1130 may be configured as or otherwise support a means for decrementing a value of a counter associated with the SA gap based at least in part on performing the FBEAM operation on the SA gap. In some examples, the SA gap is selected for the FBEAM operation based at least in part on a priority of the address, and the FBEAM component 1130 may be configured as or otherwise support a means for determining, based at least in part on decrementing the value, that the value of the counter is below a threshold. In some examples, the SA gap is selected for the FBEAM operation based at least in part on a priority of the address, and the FBEAM component 1130 may be configured as or otherwise support a means for removing the address associated with the SA gap from the queue based at least in part on the value of the counter being below the threshold.

In some examples, the SA gap is coupled with a subarray of the memory array, and the sub-word line component 1140 may be configured as or otherwise support a means for decreasing, during the FBEAM operation, a second voltage of word lines in the subarray from a first level to a second level.

In some examples, the sub-word line component 1140 may be configured as or otherwise support a means for activating one or more second switching circuits coupled with a sub-word line driver for the subarray, where the voltage of the word lines is decreased during the FBEAM operation based at least in part on activating the one or more second switching circuits.

In some examples, the described functionality of the memory system 1120, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 1120, or various components thereof, may be implemented at least in part by instructions (e.g., stored in memory, non-transitory computer-readable medium) executable by such at least one processor.

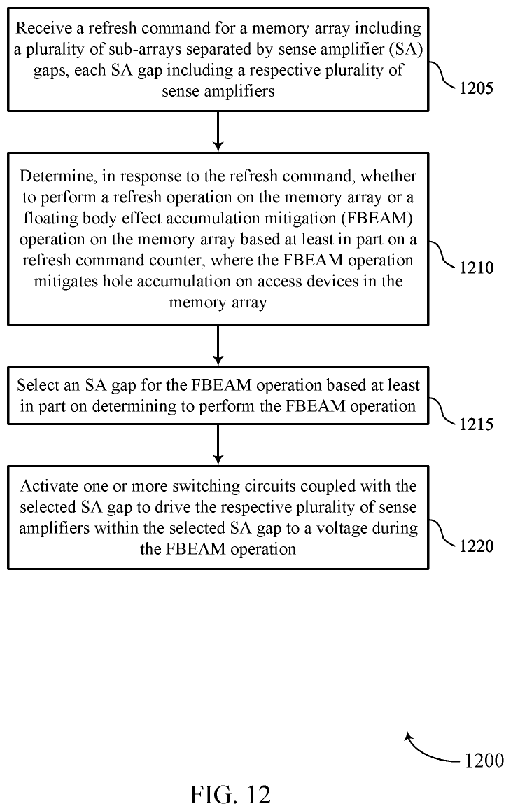

FIG. 12 shows a flowchart illustrating a method 1200 that supports FBEAM operations in a memory system in accordance with examples as disclosed herein. The operations of method 1200 may be implemented by a memory system or its components as described herein. For example, the operations of method 1200 may be performed by a memory system as described with reference to FIGS. 1 through 11. In some examples, a memory system may execute a set of instructions to control the functional elements of the device to perform the described functions. Additionally, or alternatively, the memory system may perform aspects of the described functions using special-purpose hardware.

At 1205, the method may include receiving a refresh command for a memory array including a plurality of sub-arrays separated by sense amplifier (SA) gaps, each SA gap including a respective plurality of sense amplifiers. In some examples, aspects of the operations of 1205 may be performed by a communication component 1125 as described with reference to FIG. 11.

At 1210, the method may include determining, in response to the refresh command, whether to perform a refresh operation on the memory array or a FBEAM operation on the memory array based at least in part on a refresh command counter, where the FBEAM operation mitigates hole accumulation on access devices in the memory array. In some examples, aspects of the operations of 1210 may be performed by an FBEAM component 1130 as described with reference to FIG. 11.

At 1215, the method may include selecting an SA gap for the FBEAM operation based at least in part on determining to perform the FBEAM operation. In some examples, aspects of the operations of 1215 may be performed by an FBEAM component 1130 as described with reference to FIG. 11.

At 1220, the method may include activating one or more switching circuits coupled with the selected SA gap to drive the respective plurality of sense amplifiers within the selected SA gap to a voltage during the FBEAM operation. In some examples, aspects of the operations of 1220 may be performed by an SA gap component 1135 as described with reference to FIG. 11.

In some examples, an apparatus as described herein may perform a method or methods, such as the method 1200. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a refresh command for a memory array including a plurality of sub-arrays separated by sense amplifier (SA) gaps, each SA gap including a respective plurality of sense amplifiers; determining, in response to the refresh command, whether to perform a refresh operation on the memory array or a FBEAM operation on the memory array based at least in part on a refresh command counter, where the FBEAM operation mitigates hole accumulation on access devices in the memory array; selecting an SA gap for the FBEAM operation based at least in part on determining to perform the FBEAM operation; and activating one or more switching circuits coupled with the selected SA gap to drive the respective plurality of sense amplifiers within the selected SA gap to a voltage during the FBEAM operation.

Aspect 2: The method, apparatus, or non-transitory computer-readable medium of aspect 1, where each sense amplifier in the respective plurality of sense amplifiers within the selected SA gap is coupled with a respective pair of digit lines and the method, apparatuses, and non-transitory computer-readable medium further includes operations, features, circuitry, logic, means, or instructions, or any combination thereof for activating the respective plurality of sense amplifiers within the selected SA gap based at least in part on activating the one or more switching circuits, where the respective pair of digit lines coupled with each sense amplifier in the respective plurality of sense amplifiers is driven to the voltage based at least in part on activating the respective plurality of sense amplifiers.

Aspect 3: The method, apparatus, or non-transitory computer-readable medium of any of aspects 1 through 2, further including operations, features, circuitry, logic, means, or instructions, or any combination thereof for comparing a value of a refresh counter to an address ratio value, where the value of the refresh counter represents a quantity of refresh operations that have been performed on the memory array, and where the FBEAM operation is determined to be performed based at least in part on the value of the refresh counter being equal to the address ratio value.

Aspect 4: The method, apparatus, or non-transitory computer-readable medium of aspect 3, further including operations, features, circuitry, logic, means, or instructions, or any combination thereof for resetting the value of the refresh counter based at least in part on performing the FBEAM operation.

Aspect 5: The method, apparatus, or non-transitory computer-readable medium of any of aspects 1 through 4, further including operations, features, circuitry, logic, means, or instructions, or any combination thereof for transmitting, over a row address bus, an indication of value of a counter to a bank including the memory array, where the value of the counter represents a quantity of FBEAM operations that have been performed on the memory array, and where the SA gap is selected for the FBEAM operation based at least in part on the value being associated with an address of the SA gap.

Aspect 6: The method, apparatus, or non-transitory computer-readable medium of aspect 5, further including operations, features, circuitry, logic, means, or instructions, or any combination thereof for incrementing the value of the counter based at least in part on performing the FBEAM operation.

Aspect 7: The method, apparatus, or non-transitory computer-readable medium of any of aspects 1 through 6, where the SA gap is selected for the FBEAM operation based at least in part on an address associated with the SA gap being included in a list of addresses stored by a queue and the list of addresses includes addresses associated with SA gaps for FBEAM operations.

Aspect 8: The method, apparatus, or non-transitory computer-readable medium of aspect 7, further including operations, features, circuitry, logic, means, or instructions, or any combination thereof for incrementing, based at least in part on an activate command for the SA gap, a value of a counter associated with the SA gap; determining that the value of the counter satisfies a threshold; and adding the address associated with the SA gap to the queue based at least in part on the value of the counter satisfying the threshold, where selecting the SA gap is based at least in part on adding the address to the queue.

Aspect 9: The method, apparatus, or non-transitory computer-readable medium of aspect 8, further including operations, features, circuitry, logic, means, or instructions, or any combination thereof for determining that the address associated with the SA gap is already in the queue and increasing a priority of the address based at least in part on the address already being in the queue, where selecting the SA gap is based at least in part on the priority of the address in the queue.

Aspect 10: The method, apparatus, or non-transitory computer-readable medium of any of aspects 8 through 9, further including operations, features, circuitry, logic, means, or instructions, or any combination thereof for activating the respective plurality of sense amplifiers in the SA gap based at least in part on the activate command, where the value of the counter associated with the SA gap is incremented based at least in part on activating the respective plurality of sense amplifiers.

Aspect 11: The method, apparatus, or non-transitory computer-readable medium of aspect 10, further including operations, features, circuitry, logic, means, or instructions, or any combination thereof for determining that the respective plurality of sense amplifiers have been activated for a threshold duration, where the value of the counter is incremented based at least in part on the respective plurality of sense amplifiers having been activated for the threshold duration.

Aspect 12: The method, apparatus, or non-transitory computer-readable medium of any of aspects 7 through 11, where the SA gap is selected for the FBEAM operation based at least in part on a priority of the address and the method, apparatuses, and non-transitory computer-readable medium further includes operations, features, circuitry, logic, means, or instructions, or any combination thereof for decrementing a value of a counter associated with the SA gap based at least in part on performing the FBEAM operation on the SA gap; determining, based at least in part on decrementing the value, that the value of the counter is below a threshold; and removing the address associated with the SA gap from the queue based at least in part on the value of the counter being below the threshold.

Aspect 13: The method, apparatus, or non-transitory computer-readable medium of any of aspects 1 through 12, where the SA gap is coupled with a subarray of the memory array and the method, apparatuses, and non-transitory computer-readable medium further includes operations, features, circuitry, logic, means, or instructions, or any combination thereof for decreasing, during the FBEAM operation, a second voltage of word lines in the subarray from a first level to a second level.

Aspect 14: The method, apparatus, or non-transitory computer-readable medium of aspect 13, further including operations, features, circuitry, logic, means, or instructions, or any combination thereof for activating one or more second switching circuits coupled with a sub-word line driver for the subarray, where the voltage of the word lines is decreased during the FBEAM operation based at least in part on activating the one or more second switching circuits.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: An apparatus, including: a plurality of sense amplifier (SA) gaps between subarrays of a memory array, each SA gap including a plurality of sense amplifiers; circuitry configured to determine whether to perform a refresh operation on the memory array or a FBEAM operation on the memory array based at least in part on a refresh command counter, where the FBEAM operation mitigates hole accumulation on access devices in the memory array; and a plurality of switching circuits each of which is coupled with a respective plurality of sense amplifiers in a respective SA gap, where a switching circuit for a SA gap is configured to selectively supply the respective plurality of sense amplifiers within the SA gap with a voltage during the FBEAM operation, and where the respective plurality of sense amplifiers are configured to drive one or more digit lines to the voltage.

Aspect 16: The apparatus of aspect 15, further including: a counter configured to count a quantity of FBEAM operations performed on the memory array, where a value of the counter is associated with a respective address of the SA gap of the plurality of SA gaps.

Aspect 17: The apparatus of aspect 16, further including: a decoder configured to control the plurality of switching circuits based at least in part on the value of the counter.

Aspect 18: The apparatus of any of aspects 15 through 17, further including: a plurality of counters each of which is associated with a respective SA gap of the plurality of SA gaps, where a counter for an SA gap is configured to increment a value of the counter based at least in part on activation of the respective plurality of sense amplifiers in that SA gap.

Aspect 19: The apparatus of aspect 18, further including: a queue configured to store a list of addresses for FBEAM operations, the list of addresses associated with SA gaps of the plurality of SA gaps; and logic configured add addresses to the queue based at least in part on values of the plurality of counters.

Aspect 20: The apparatus of aspect 19, further including: a decoder coupled with the queue and configured to control the plurality of switching circuits based at least in part on an address from the queue.

Aspect 21: The apparatus of any of aspects 15 through 20, further including: a plurality of sub-word line driver (SWD) gaps coupled with the subarrays, each SWD gap including a respective plurality of sub-word line drivers; and a plurality of second switching circuits each of which is coupled with a respective plurality of sub-word line drivers in a respective SWD gap, where a second switching circuit for a SWD gap is configured to selectively supply the respective plurality of sub-word line drivers within the SWD gap with a second voltage during the FBEAM operation, and where the respective plurality of sub-word line drivers are configured to drive one or more word lines to the voltage.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a plurality of sense amplifier (SA) gaps between subarrays of a memory array, each SA gap comprising a plurality of sense amplifiers;
circuitry configured to determine whether to perform a refresh operation on the memory array or a FBEAM operation on the memory array based at least in part on a refresh command counter, wherein the FBEAM operation mitigates hole accumulation on access devices in the memory array; and
a plurality of switching circuits each of which is coupled with a respective plurality of sense amplifiers in a respective SA gap, wherein a switching circuit for a SA gap is configured to selectively supply the respective plurality of sense amplifiers within the SA gap with a voltage during the FBEAM operation, and wherein the respective plurality of sense amplifiers are configured to drive one or more digit lines to the voltage.

2. The apparatus of claim 1, further comprising:
a counter configured to count a quantity of FBEAM operations performed on the memory array, wherein a value of the counter is associated with a respective address of the SA gap of the plurality of SA gaps.

3. The apparatus of claim 2, further comprising:
a decoder configured to control the plurality of switching circuits based at least in part on the value of the counter.

4. The apparatus of claim 1, further comprising:
a plurality of counters each of which is associated with a respective SA gap of the plurality of SA gaps, wherein a counter for an SA gap is configured to increment a value of the counter based at least in part on activation of the respective plurality of sense amplifiers in that SA gap.

5. The apparatus of claim 4, further comprising:
a queue configured to store a list of addresses for FBEAM operations, the list of addresses associated with SA gaps of the plurality of SA gaps; and
logic configured add addresses to the queue based at least in part on values of the plurality of counters.

6. The apparatus of claim 5, further comprising:
a decoder coupled with the queue and configured to control the plurality of switching circuits based at least in part on an address from the queue.

7. The apparatus of claim 1, further comprising:
a plurality of sub-word line driver (SWD) gaps coupled with the subarrays, each SWD gap comprising a respective plurality of sub-word line drivers; and
a plurality of second switching circuits each of which is coupled with a respective plurality of sub-word line drivers in a respective SWD gap, wherein a second switching circuit for a SWD gap is configured to selectively supply the respective plurality of sub-word line drivers within the SWD gap with a second voltage during the FBEAM operation, and wherein the respective plurality of sub-word line drivers are configured to drive one or more word lines to the voltage.

8. A method, comprising:
receiving a refresh command for a memory array comprising a plurality of sub-arrays separated by sense amplifier (SA) gaps, each SA gap comprising a respective plurality of sense amplifiers;
determining, in response to the refresh command, whether to perform a refresh operation on the memory array or a FBEAM operation on the memory array based at least in part on a refresh command counter, wherein the FBEAM operation mitigates hole accumulation on access devices in the memory array;
selecting an SA gap for the FBEAM operation based at least in part on determining to perform the FBEAM operation; and
activating one or more switching circuits coupled with the selected SA gap to drive the respective plurality of sense amplifiers within the selected SA gap to a voltage during the FBEAM operation.

9. The method of claim 8, wherein each sense amplifier in the respective plurality of sense amplifiers within the selected SA gap is coupled with a respective pair of digit lines, the method further comprising:
activating the respective plurality of sense amplifiers within the selected SA gap based at least in part on activating the one or more switching circuits, wherein the respective pair of digit lines coupled with each sense amplifier in the respective plurality of sense amplifiers is driven to the voltage based at least in part on activating the respective plurality of sense amplifiers.

10. The method of claim 8, further comprising:
comparing a value of a refresh counter to an address ratio value, wherein the value of the refresh counter represents a quantity of refresh operations that have been performed on the memory array, and wherein the FBEAM operation is determined to be performed based at least in part on the value of the refresh counter being equal to the address ratio value.

11. The method of claim 10, further comprising:
resetting the value of the refresh counter based at least in part on performing the FBEAM operation.

12. The method of claim 8, further comprising:
transmitting, over a row address bus, an indication of value of a counter to a bank comprising the memory array, wherein the value of the counter represents a quantity of FBEAM operations that have been performed on the memory array, and wherein the SA gap is selected for the FBEAM operation based at least in part on the value being associated with an address of the SA gap.

13. The method of claim 12, further comprising:
incrementing the value of the counter based at least in part on performing the FBEAM operation.

14. The method of claim 8, wherein the SA gap is selected for the FBEAM operation based at least in part on an address associated with the SA gap being included in a list of addresses stored by a queue, and wherein the list of addresses comprises addresses associated with SA gaps for FBEAM operations.

15. The method of claim 14, further comprising:
incrementing, based at least in part on an activate command for the SA gap, a value of a counter associated with the SA gap;
determining that the value of the counter satisfies a threshold; and
adding the address associated with the SA gap to the queue based at least in part on the value of the counter satisfying the threshold, wherein selecting the SA gap is based at least in part on adding the address to the queue.

16. The method of claim 15, further comprising:
determining that the address associated with the SA gap is already in the queue; and
increasing a priority of the address based at least in part on the address already being in the queue, wherein selecting the SA gap is based at least in part on the priority of the address in the queue.

17. The method of claim 15, further comprising:
activating the respective plurality of sense amplifiers in the SA gap based at least in part on the activate command, wherein the value of the counter associated with the SA gap is incremented based at least in part on activating the respective plurality of sense amplifiers.

18. The method of claim 17, further comprising:
determining that the respective plurality of sense amplifiers have been activated for a threshold duration, wherein the value of the counter is incremented based at least in part on the respective plurality of sense amplifiers having been activated for the threshold duration.

19. The method of claim 14, wherein the SA gap is selected for the FBEAM operation based at least in part on a priority of the address, the method further comprising:
decrementing a value of a counter associated with the SA gap based at least in part on performing the FBEAM operation on the SA gap;
determining, based at least in part on decrementing the value, that the value of the counter is below a threshold; and
removing the address associated with the SA gap from the queue based at least in part on the value of the counter being below the threshold.

20. The method of claim 8, wherein the SA gap is coupled with a subarray of the memory array, the method further comprising:
decreasing, during the FBEAM operation, a second voltage of word lines in the subarray from a first level to a second level; and
activating one or more second switching circuits coupled with a sub-word line driver for the subarray, wherein the voltage of the word lines is decreased during the FBEAM operation based at least in part on activating the one or more second switching circuits.
